(19) United States
(12) Patent Application Publication
(10) Pub. No.: US 2007/0105314 A1
(43) Pub. Date: May 10, 2007

(54) Process for manufacturing a non-volatile memory device

(75) Inventors: Luca Pividori, Curno (BG) (IT); Claudio Crippa, Concorezzo (MI) (IT)

Correspondence Address: JENKENS & GILCHRIST, PC, 1445 ROSS AVENUE, SUITE 3200, DALLAS, TX, 75202, US

(73) Assignee: STMicroelectronics S.r.l., Agrate Brianza (IT)

(21) Appl. No.: 11/528,500

(22) Filed: Sep. 27, 2006

(30) Foreign Application Priority Data
Sep. 30, 2005 (EP) 05425681.3

(51) Int. Cl. H01L 21/336

(52) U.S. Cl. 438/258

(57) ABSTRACT

A non volatile memory device is integrated on a semiconductor substrate and includes a matrix of memory cells with an associated circuitry. The process for forming the memory device includes forming in the semiconductor substrate first dielectric insulation regions of the matrix to define and insulate first active areas of the matrix from each other, and forming in the semiconductor substrate second dielectric insulation regions of the associated circuitry to define and insulate second active areas of the circuitry from each other. At least one dielectric layer is formed on the first and second active areas. A first conductive layer is deposited on the whole device, and floating gate electrodes of the memory cells of the matrix are defined in the first conductive layer, with the first conductive layer being removed from the associated circuitry. A blanket etching is then carried out on the whole device to remove a surface portion of the first and second dielectric insulation regions which are not shielded by the floating gate electrodes.

### PRIORITY CLAIM

The present application claims priority from European Patent Application No. 05425681.3 filed Sep. 30, 2005, the disclosure of which is hereby incorporated by reference.

### BACKGROUND OF THE INVENTION

1. Technical Field of the Invention

The present invention relates to a process for manufacturing a non volatile memory device.

More specifically, the invention relates to a process for manufacturing a non volatile memory integrated on semiconductor substrate device comprising one matrix of memory cells with an associated circuitry, the process comprising the steps of: forming, in said semiconductor substrate, first dielectric insulation regions of said matrix so as to define and insulate the active areas of said matrix from each another, forming, in said semiconductor substrate, second dielectric insulation regions of said circuitry so as to define and insulate the active areas of said circuitry from each other, forming at least one first dielectric layer on said active areas, depositing a first conductive layer on the whole said device, defining floating gate electrodes of said memory cells of said matrix in said first conductive layer, and removing, at least partially, said first conductive layer from the circuitry.

The invention particularly, but not exclusively, relates to a process for manufacturing memory devices of the Flash type and the following description is made with reference to this field of application by way of illustration only.

2. Description of Related Art

As it is well known, non volatile memory electronic devices integrated on semiconductor substrate, for example of the Flash type, comprise a plurality of non volatile memory cells organized in a matrix.

Each single non volatile memory cell comprises a MOS transistor wherein the gate electrode, placed above the channel region, is floating, i.e., it has a high impedance in DC towards all the other terminals of the same cell and of the circuit wherein the cell is inserted.

The cell also comprises a second electrode, called control gate, which is capacitively coupled to the floating gate electrode through a intermediate dielectric layer, a so called interpoly. This second electrode is driven through suitable control voltages. The other electrodes of the transistor are the usual drain and source terminals.

The matrix of memory cells is associated with a control circuitry comprising at least one conventional MOS transistor having a source region and a drain region separated by a channel region. A gate electrode is then formed on the channel region and insulated therefrom by means of a gate oxide layer.

Each electronic component realizing the memory electronic device is generally realized in a respective active area which is insulated from the adjacent components by means of dielectric insulation regions realized in the semiconductor substrate.

The presence of dielectric insulation regions is one of the main sources of displacement, i.e., crystallographic faults, which are created inside silicon semiconductor substrates wherein these non volatile memory devices are realized.

The presence of these displacements is particularly evident when the dielectric insulation regions are realized by means of STI (Shallow Trench Isolation).

The manufacturing steps to form a non volatile memory device comprising a matrix of memory cells and a corresponding circuitry, wherein the dielectric insulation regions have been realized by means of STI, comprise for example:

forming sacrificial dielectric layers, comprising for example an oxide layer called PADOX (Pad-OXide) and if necessary a silicon nitride layer, on the whole semiconductor substrate,

defining active areas for the circuitry and for the memory matrix by means of a conventional photolithographic technique which provides the formation of a photolithographic mask on the semiconductor substrate, wherein openings are defined,

removing portions of the sacrificial dielectric layers and of the semiconductor substrate through these openings, by means of chemical etching for example of the dry type, so as to form trenches inside the semiconductor substrate itself,

deposition through CVD (Chemical Vapor Deposition) or HDPCVD (High Density Plasma CVD) of a dielectric layer which has the aim of filling the trenches, after having removed the photolithographic mask,

planarizing the device by means of CMP (Chemical Mechanical Polishing), and

if necessary deposition of further sacrificial layers, for example called SAROX (Sacrificial Oxide).

The shape and the characteristics of the trenches which are realized through the deposition in plasma are thus very important. In fact the depth of the trenches, their shape, the transversal dimensions, and the roughness of the various surfaces have great implications on a lot of parameters: the efficiency of the electric insulation, the quality of the active area, the presence or not of the crystallographic displacements.

A conventional process for manufacturing a non volatile memory device further comprises the steps of:

removal of the sacrificial layers from the active areas of the memory matrix by means of suitable etching (for example, of the wet or dry type) so as to expose the semiconductor substrate inside these active areas of the memory matrix,

forming an active oxide layer also known as tunnel oxide in the active areas, for example by means of a thermal oxidation layer;

depositing a first conductive layer, for example of polysilicon, on the whole device;

defining floating gate electrodes in the matrix region with a first polysilicon layer and elimination thereof from the circuitry;

depositing a dielectric layer (called an interpoly), for example ONO (Oxide Nitrate Oxide);

forming a photolithographic mask called MATRIX on the matrix of memory cells, so as to shield the matrix, to eliminate, by means of chemical and physical etching, the interpoly layer and other possible oxide layers present in the circuitry;

forming one or more dielectric layers, for example gate active oxide layers in the circuitry and in the memory matrix, by means of a thermal oxidation step;

depositing a second conductive layer, for example of polysilicon;

defining the control gate electrodes of the matrix cells and the gate electrodes of the circuitry transistors in the second polysilicon layer; and

forming the source and drain regions of the matrix cells, of the transistors and of the metallization layers.

Although advantageous under several aspects, this first solution has the drawback of generating stresses inside the insulation regions mainly due to the steps of: formation of the trenches in the semiconductor substrate, filling of the trenches with an oxide layer through CVD, and carrying out thermal oxidation steps.

There is accordingly a need in the art to provide a method to reduce the stress induced in the areas of the circuitry of the memory device through a process which ensures a flexibility of intervention not allowed by the methods generally used and known.

### SUMMARY OF THE INVENTION

In one aspect, the solution idea underlying the present invention is that of introducing, in the standard process flow for manufacturing a non volatile memory electronic device, a partial etching step of the dielectric layers present on the non volatile memory electronic device, immediately after the definition of the floating gate electrodes.

In an embodiment, a process for manufacturing a non volatile memory integrated on semiconductor substrate device comprising one matrix of memory cells with an associated circuitry, comprises the steps of: forming, in said semiconductor substrate, first dielectric insulation regions of said matrix so as to define and insulate the active areas of said matrix from each another, forming, in said semiconductor substrate, second dielectric insulation regions of said circuitry so as to define and insulate the active areas of said circuitry from each other, forming at least one first dielectric layer on said active areas, depositing a first conductive layer on the whole said device, defining floating gate electrodes of said memory cells of said matrix in said first conductive layer, and removing, at least partially, said first conductive layer from the circuitry.

In an embodiment, a process for manufacturing a non volatile memory device integrated on semiconductor substrate comprising a matrix of memory cells, comprises the steps of: forming in said semiconductor substrate first dielectric insulation regions of said matrix so as to define and insulate from each other first active areas of said matrix, forming in said semiconductor substrate second dielectric insulation regions for associated circuitry so as to define and insulate from each other second active areas of the associated circuitry, forming at least one first dielectric layer on the first and second active areas, depositing a first conductive layer, defining floating gate electrodes of said memory cells of said matrix in said first conductive layer, the floating gate electrodes partially overlapping first dielectric insulation regions adjacent the first active areas of said matrix, removing at least partially said first conductive layer from the associated circuitry, and carrying out a blanket etching on the whole device to remove a surface portion of said first and second dielectric insulation regions not shielded by said floating gate electrodes.

In another embodiment, a process for manufacturing a non volatile memory device integrated on semiconductor substrate comprising a matrix of memory cells, comprises the steps of: forming in said semiconductor substrate dielectric insulation regions of said matrix so as to define and insulate from each other active areas of said matrix, forming at least one first dielectric layer on the active areas, depositing a first conductive layer, defining floating gate electrodes of said memory cells of said matrix in said first conductive layer, and carrying out a blanket etching to remove a surface portion of said dielectric insulation regions not shielded by said floating gate electrodes.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIGS. 1 to 6 are respective schematic section views of a portion of integrated circuit during the successive steps of a process according to the present invention; and

FIG. 7 shows an enlarged detail of a portion of integrated circuit.

### DETAILED DESCRIPTION OF THE DRAWINGS

The process steps described hereafter do not form a complete process flow for manufacturing integrated circuits. The present invention can be put into practice together with the manufacturing techniques of the integrated circuits currently used in the field, and only those process steps being commonly used in the field and necessary for the comprehension of the present invention are included.

The figures showing cross sections of portions of an integrated circuit during manufacture are not drawn to scale, but they are instead drawn so as to show the important characteristics of the invention.

With reference to the figures, a process is described for manufacturing a non volatile memory device 1 integrated on semiconductor substrate 2, which comprises a matrix 3 of non volatile memory cells and an associated circuitry 4.

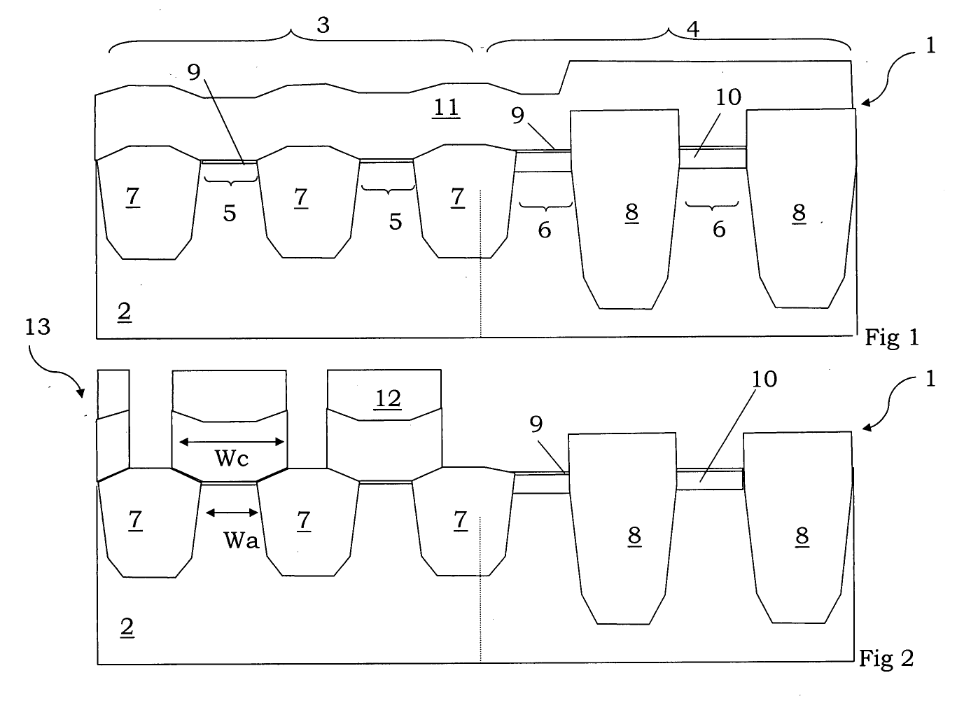

With particular reference to FIG. 1, on the semiconductor substrate 2 sacrificial dielectric layers 10 are formed, if necessary, comprising for example an oxide layer called PADOX (Pad-OXide).

In the semiconductor substrate 2, dielectric insulation regions 7 for the matrix 3 are then formed which define and insulate from each other active areas 5 of the matrix 3 and dielectric insulation regions 8 of the circuitry 4 are formed which define and insulate from each other active areas 6 of the circuitry 4.

These dielectric insulation regions 7, 8 are formed by a dielectric layer, for example by a field oxide layer, and they are for example of the STI type, then realized as described with reference to the prior art.

Moreover the dielectric insulation regions 8 of the circuitry 4 can be deeper in the semiconductor substrate 2 than in the dielectric insulation regions 7 of the matrix 3, and have a greater height of the insulation regions 7 of the matrix 3 with respect to the surface of the semiconductor substrate 2.

Once the sacrificial dielectric layers 10, if present, are removed from the active areas 5 of the matrix 3, the process for manufacturing a non volatile memory device 1 then goes on with the formation of a dielectric layer 9, for example a tunnel oxide layer on the whole device 1.

In particular, in the matrix 3 of memory cells this tunnel oxide layer 9 is formed directly on the semiconductor substrate 2, while in the circuitry 4 this layer is overlapped onto sacrificial dielectric layers 10 if already present in the circuitry 4.

The process then goes on by means of deposition of a first conductive layer 11 for example of polysilicon on the whole device 1.

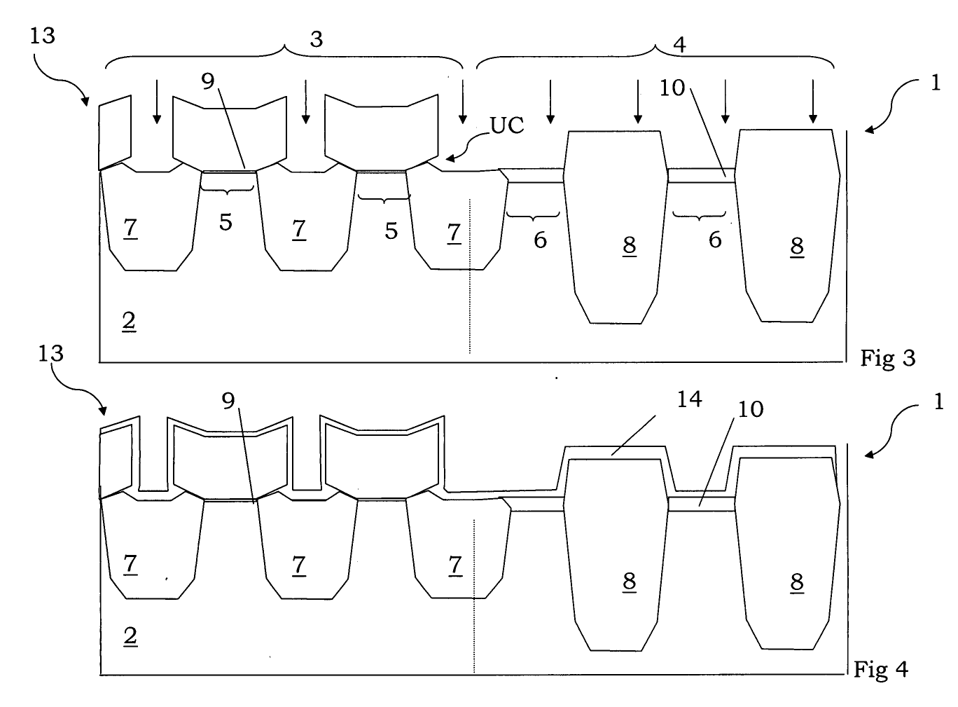

As shown in FIG. 2, a first photolithographic mask 12 is then formed on the semiconductor substrate 2, wherein openings are defined. Through these openings, by means of etching for example of the dry type, portions of the first polysilicon layer 11 are removed so as to define floating gate electrodes 13 in the region of the matrix 3 and to completely eliminate this first polysilicon layer 11 from the circuitry 4.

Nothing forbids that portions of this first polysilicon layer 11 can remain inside the circuitry 4.

Advantageously, the floating gate electrodes 13 in the region of the matrix 3 have a first width Wc greater than a second width Wa of the active areas 5 of the matrix 3.

Once the first photolithographic mask 12 is removed, according to the invention, a blanket etching step is carried out (for example, without the help of a lithographic masking) and it thus etches all the structures of the device both in matrix and in circuitry, for removing a surface portion of the dielectric insulation regions 7, 8 and of the sacrificial dielectric layers 10 not shielded by the floating gate electrodes 13, as shown in FIG. 3.

In particular, this etching step removes a surface portion of the insulation regions 7 of the matrix 3, of the insulation regions 8 of the circuitry 4 and of the sacrificial dielectric layers 10 if present in circuitry 4, as well as the tunnel oxide layer 9 present in circuitry 4. In particular if the sacrificial layers 10 are not present in the circuitry 4 only the tunnel oxide layer 9 tunnel is removed, completely or at least partially.

In particular, this blanket etching step must be such as to not expose the active areas 5 present in matrix 3 and thus etch the tunnel oxide layer 9 present in matrix 3.

Advantageously according to the invention, the blanket etching step is of the isotropic type, and it is realized for example by means of BOE (Buffered Oxide Etch) in wet.

By carrying out this blanket etching step of the isotropic type, also portions of the insulation regions 7 are removed which are below the floating gate electrode 13, whereby a small trench (or under-cut) UC is located below the floating gate electrodes on bottom of the wall of the first polysilicon conductive layer.

By means of a blanket etching step of the BOE type, for example, a surface portion of the exposed dielectric layers whose thickness is comprised in a range 50 Å to 300 Å is removed.

Nothing forbids that however the blanket etching step, according to the invention, is of the anisotropic type, for example of the dry type in plasma.

The manufacturing process of the memory device 1 then goes on with the conventional process steps comprising:

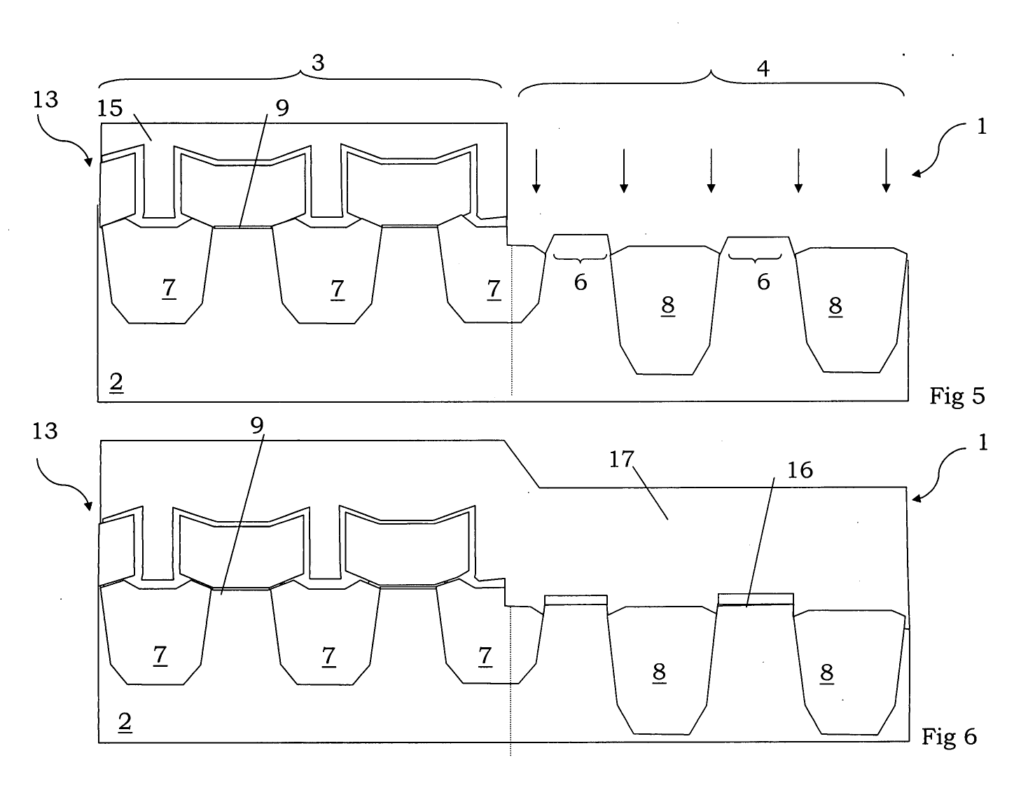

depositing a dielectric layer 14 (called an interpoly), for example ONO (Oxide Nitrate Oxide) on the whole device, as shown in FIG. 4;

forming a second photolithographic mask 15, called the MATRIX mask on the memory matrix 3, and etching the interpoly dielectric layer 14 and other oxide layers 10, if present, in the circuitry 4, until the active areas of the circuitry 4 are exposed. As shown in FIG. 5, this latter etching step of the interpoly dielectric layer 14 and, if present, of the other oxide layers 10 also removes a further surface portion of the insulation regions 8 of the circuitry 4.

Advantageously, this etching step provides a first etching step of the interpoly dielectric layer 14 by means of an etching of the anisotropic type and a second isotropic etching step of the oxide layers 10 of the circuitry 4, for example by using a solution of the BOE type.

As shown in FIG. 6, the process for manufacturing a non volatile memory device 1 also comprises the steps of:

forming one or more dielectric layers 16, for example gate active oxides, in the circuitry 4, for example by means of a thermal oxidation step. Clearly, this latter thermal oxidation step also interests the matrix; however the presence of the dielectric layer 14 prevents the growth of these oxides in matrix and their effect is to densify the dielectric layer 14 itself improving its performances,

depositing a second conductive layer 17 for example of polysilicon.

Then control gate electrodes of the matrix 3 cells and gate electrodes of transistors of the circuitry 4 are defined in the second polysilicon layer 17, the source and drain regions of the transistors and the metallization layers are realized in a conventional way.

According to the invention then in the conventional process flow for the manufacturing of memory devices, a supplementary blanket etching step is added to remove a surface portion of the insulation regions 7, 8 and of the dielectric sacrificial layers 10 not shielded by the floating gate electrodes 13 before the formation of the interpoly dielectric layer 14 (see, between FIGS. 3 and 4).

Advantageously, during this blanket etching step in matrix 3 there are no critical areas which could be damaged by the etching and thus, in circuitry, the removal of parts of the sacrificial dielectric layers 10 on the active areas is provided. These oxide layers 10 must be in fact completely removed before proceeding with the formation of one or more gate oxide layers in circuitry.

Still advantageously according to the invention, introducing this supplementary blanket etching step also allows to minimize the arise of unsticking problems of the resist layer the mask 15 matrix is generally made of. This unsticking phenomenon, due to the etching step conventionally used to “clean” the circuitry of the sacrificial dielectric layers, shows itself in particular when lithographic resists of the DUV type are used, which are by now conventional for the manufacturing of semiconductor memory devices with sizes smaller than 0.13 μm, and it occurs in particular when these resist layers are subjected to very long isotropic etchings, for example BOE in wet, i.e., etchings which remove equivalent thermal oxide layers with thickness greater than 500 Å. Thus, by introducing the supplementary blanket etching step according to an aspect of the invention it is possible to increase the thickness of the removed layers with respect to the one obtained with a single conventional etching step, which is carried out after the formation of the matrix mask 15, without jeopardizing the performance of the materials used.

Moreover it is known that during the planarization operations used for manufacturing the insulation regions of the STI type realized by means of CMP, on these insulation regions micro-scratches can be formed which are filled by the polysilicon layer 11 subsequently formed on the device 1. However during the successive definition step of the floating gate electrodes 13, polysilicon residues remain incorporated in the micro-scratches.

These polysilicon residues, even if they are minimal and not able to generate real short circuits between two floating gates, can represent however a possible problem of reliability for memory devices, in particular of the multilevel Flash type; in fact the polysilicon residue incorporated in the micro-scratch is a preferential path for the electrical charges which may in this way go out of a cell and pass to the adjacent one generating the flip-bit (charge exchange) phenomenon with subsequent loss of the information previously stored in the single memory cell. The blanket etching step, according to the invention, in fact allows to eliminate the polysilicon residue present in the micro-scratch, eliminating the portion of insulation region, i.e., of the field oxide layer surrounding it.

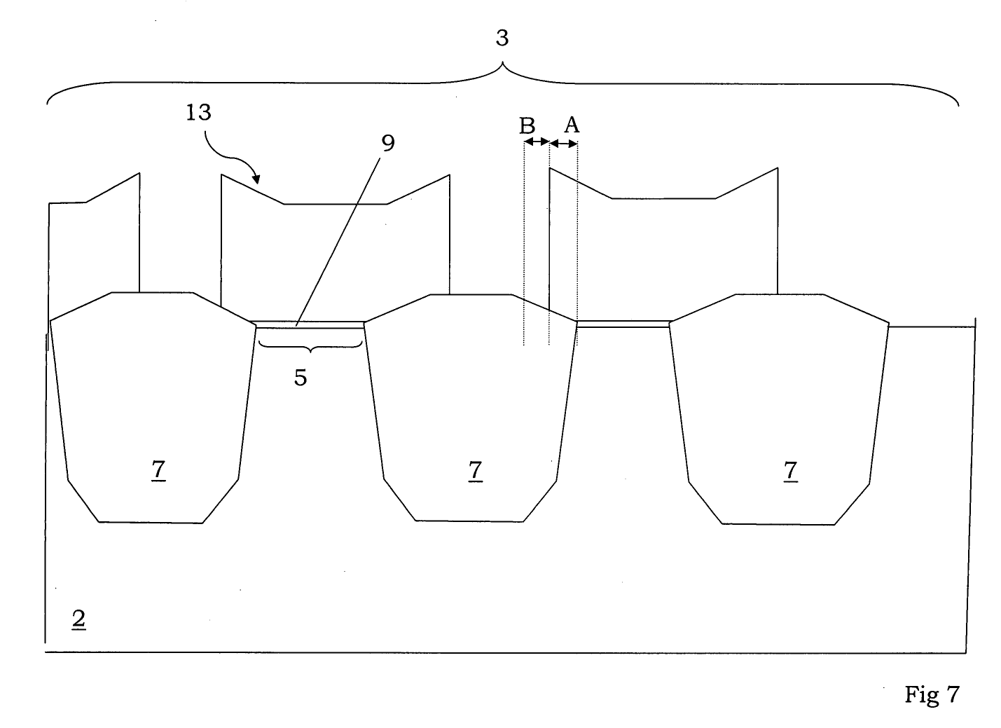

Advantageously according to the invention, as shown in FIG. 7, when evaluating the time range wherein the supplementary blanket etching is to be carried out according to the invention what follows is taken into consideration:

the distance A between the side wall of the floating gate electrode 13 and the edge of the active area 5 wherein these electrodes are defined and formed,

the overlay specifications relative to the technology and/or to the product, which determined the possible extent of a misalignment, indicated with the distance B, of the floating gate electrode 13 with respect to the active area 5.

From the evaluation of these parameters it is possible to determine the maximum time possible to carry out the blanket etching without incurring an infiltration of the etching solution which can go and etch also the tunnel oxide dielectric layer 9 of the cell.

Advantageously, if the blanket etching is of the isotropic type the devices realized with this method can be clearly identified by means of a simple SEM section in the region of the matrix cells, where the characteristic morphology with under-cut (UV, see FIG. 3) caused by the blanket etching carried out before the deposition of the interpoly dielectric layer is present.

Moreover, for flash memories the blanket etching according to the invention in fact allows to lower the insulation regions 8 improving the morphology of the interface portion between insulation regions 8 and active areas. The quality of the oxide layers which will be after formed, and the stress release and thus the reduction of the formations of displacements are improved.

Although in the description particular reference has been made to a process for manufacturing a two-level non volatile memory device the process according to the invention can be advantageously applied to multilevel non volatile memory devices.

Although preferred embodiments of the device of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A process for manufacturing a non volatile memory device integrated on semiconductor substrate comprising a matrix of memory cells, the process comprising the steps of:
forming in said semiconductor substrate first dielectric insulation regions of said matrix so as to define and insulate from each other first active areas of said matrix,
forming in said semiconductor substrate second dielectric insulation regions for associated circuitry so as to define and insulate from each other second active areas of the associated circuitry,
forming at least one first dielectric layer on the first and second active areas,
depositing a first conductive layer,
defining floating gate electrodes of said memory cells of said matrix in said first conductive layer,
removing at least partially said first conductive layer from the associated circuitry, and
carrying out a blanket etching on the whole device to remove a surface portion of said first and second dielectric insulation regions not shielded by said floating gate electrodes.

2. The process according to claim 1, comprising the steps of:
forming at least one sacrificial dielectric layer before the formation step in said semiconductor substrate of said first and second dielectric insulation regions,
removing said at least one dielectric layer from said first active areas of said matrix, wherein a surface portion of said at least one sacrificial dielectric layer is also removed during the blanket etching step.

3. The process according to claim 1, wherein said blanket etching step is of the isotropic type.

4. The process according to claim 1, wherein said blanket etching step is realized by means of BOE (Buffered Oxide Etch) in wet.

5. The process according to claim 3, wherein said blanket etching step also removes portions of said insulation regions of said matrix which are below said floating gate electrode.

6. The process according to claim 1, wherein said blanket etching step is of the anistropic type.

7. The process according to claim 6, wherein said blanket etching step is of the dry type in plasma.

8. The process according to claim 1, wherein said blanket etching step removes surface portions of said dielectric insulation regions of a thickness comprised in a range from 50 Å to 300 Å.

9. The process according to claim 1, wherein said first and second dielectric insulation regions are of the STI type.

10. The process according to claim 9, wherein said first and second dielectric insulation regions are formed by the steps of:
forming trenches inside the semiconductor substrate,
deposition through CVD (Chemical Vapor Deposition) of a dielectric layer to fill said trenches,
planarizing the surface of the device by means of CMP (Chemical Mechanical Polishing).

11. The process according to claim 1, wherein said second dielectric insulation regions of said associated circuitry are deeper in the semiconductor substrate with respect to said first dielectric insulation regions of said matrix.

12. The process according to claim 1, wherein said second dielectric insulation regions of said associated circuitry have a greater height than said first dielectric insulation regions of said matrix with respect to the surface of said semiconductor substrate.

13. The process according to claim 1, wherein said floating gate electrodes of said matrix have a first width greater than a second width of said first active areas of said matrix.

14. The process according to claim 1, further comprising:
depositing a dielectric layer on the whole device;
forming a second photolithographic mask on the matrix,
etching said dielectric layer and if present other oxide layers present in said associated circuitry, until the second active areas of said associated circuitry are exposed,
forming one or more dielectric layers in the associated circuitry and in the matrix;
depositing a second conductive layer,
defining control gate electrodes of said cells of said matrix and gate electrodes of transistors of said associated circuitry in said second conductive layer,
forming source and drain regions of said memory cells and of said transistors of said associated circuitry and metallization layers.

15. The process according to claim 14, wherein said first and second conductive layers are made of a polysilicon layer.

16. The process according to claim 1, wherein said first and second dielectric insulation regions and said first dielectric layer are made of an oxide layer.

17. A process for manufacturing a non volatile memory device integrated on semiconductor substrate comprising a matrix of memory cells, the process comprising the steps of:
forming in said semiconductor substrate first dielectric insulation regions of said matrix so as to define and insulate from each other first active areas of said matrix,
forming in said semiconductor substrate second dielectric insulation regions for associated circuitry so as to define and insulate from each other second active areas of the associated circuitry,
forming at least one first dielectric layer on the first and second active areas,
depositing a first conductive layer,
defining floating gate electrodes of said memory cells of said matrix in said first conductive layer, the floating gate electrodes partially overlapping first dielectric insulation regions adjacent the first active areas of said matrix,
removing at least partially said first conductive layer from the associated circuitry, and
carrying out a blanket etching on the whole device to remove a surface portion of said first and second dielectric insulation regions not shielded by said floating gate electrodes.

18. The process according to claim 17, wherein said floating gate electrodes of said matrix have a first width greater than a second width of said first active areas of said matrix.

19. The process according to claim 17, wherein carrying out a blanket etching forms an under-cut region in the first dielectric insulation regions below the floating gate electrodes.

20. A process for manufacturing a non volatile memory device integrated on semiconductor substrate comprising a matrix of memory cells, the process comprising the steps of:
forming in said semiconductor substrate dielectric insulation regions of said matrix so as to define and insulate from each other active areas of said matrix,
forming at least one first dielectric layer on the active areas,
depositing a first conductive layer,
defining floating gate electrodes of said memory cells of said matrix in said first conductive layer, and
carrying out a blanket etching to remove a surface portion of said dielectric insulation regions not shielded by said floating gate electrodes.

21. The process of claim 20 wherein defining comprises defining the floating gate electrodes to partially overlap the dielectric insulation regions adjacent the active areas of said matrix.

22. The process according to claim 21, wherein defining still further comprises defining said floating gate electrodes of said matrix to have a first width greater than a second width of said active areas of said matrix.

23. The process according to claim 20, wherein carrying out a blanket etching forms an under-cut region in the dielectric insulation regions below the floating gate electrodes.

24. The process according to claim 20, further comprising:
depositing a dielectric layer;
depositing a second conductive layer,
defining control gate electrodes of said cells of said matrix in said second conductive layer, and
forming source and drain regions of said memory cells.
